(19) United States
(12) Patent Application Publication
(10) Pub. No.: US 2004/0161934 A1
(43) Pub. Date: Aug. 19, 2004

(54) Method for manufacturing semiconductor device

(75) Inventors: Takafumi Morikawa, Nagasaki (JP); Akihide Kashiwagi, Kanagawa (JP); Takayoshi Kato, Kanagawa (JP); Tomoyuki Hirano, Kanagawa (JP)

Correspondence Address: SONNENSCHEIN NATH & ROSENTHAL LLP, P.O. BOX 061080, WACKER DRIVE STATION, SEARS TOWER, CHICAGO, IL, 60606-1080, US

(73) Assignee: Sony Corporation

(21) Appl. No.: 10/775,932

(22) Filed: Feb. 10, 2004

(30) Foreign Application Priority Data
Feb. 14, 2003 (JP) P2003-035940

(51) Int. Cl. H01L 21/302; H01L 21/461

(52) U.S. Cl. 438/689

(57) ABSTRACT

A method for manufacturing a semiconductor device includes the steps of forming a nitrogen-containing oxide film on a substrate for use as a gate insulating film, annealing the gate insulating film in an atmosphere containing oxygen, annealing the gate insulating film in an oxygen-free, inert atmosphere, and forming an electrode film on the twice annealed gate insulating film. The method may further include the steps of forming a gate electrode by patterning of the electrode film, forming LDD, forming side wall insulating films and forming source/drain regions.

### BACKGROUND OF THE INVENTION

The present invention relates to a method for manufacturing a semiconductor device, and more particularly, to a method for making a gate insulating film in a MOS semiconductor device whose scale down is advanced.

In association with the demand for the high degree of integration and high functionality of semiconductor devices, the scale-down of a device structure of MOS silicon semiconductor devices has been pursued according to the Moore's scaling rule. In recent years, in order to push the limit of characteristic improvement of device caused by such scale-down, a so-called dual gate structure has been adopted wherein a p-type impurity-containing gate electrode is used for p-type MOS transistor (hereinafter referred to simply as PMOS) and an n-type impurity-containing gate electrode is used for n-type MOS transistor (hereinafter referred to simply as NMOS).

However, it is known that in semiconductor devices having the dual gate structure, boron (B) contained as a p-type impurity in the gate electrode of PMOS diffuses into a substrate through a gate insulating film which has been thinned in association with the scale-down of the device structure. This brings about adverse influences on device characteristics such as a lowering in mobility of carrier, an increasing number of fixed charges and the like.

To suppress the break-through of boron in the dual gate process, it has been widely used to nitride the gate insulating film. Attempts have been made to how to deal with the concentration of nitrogen so as not to degrade device characteristics (see, for example, Japanese Patent Laid-open No. 2001-291865).

The incorporation of nitrogen into the gate insulating film has presented a new problem of raising a phenomenon called NBTI (negative-bias-temperature-instability). NBTI is a phenomenon wherein nitrogen in the gate insulating film arrives at a substrate interface through thermal diffusion and becomes a trap for hole, and serves as a positive fixed charge or a scattering factor for carrier, for which the mobility or threshold of carrier gradually varies in PMOS. This is one of the factors of considerably lowering the life of semiconductor device.

### SUMMARY OF THE INVENTION

It is an object of the invention to provide a method for manufacturing a semiconductor device which enables the occurrence of NBTI phenomenon to be suppressed in a MOS transistor having a gate insulating film into which nitrogen is introduced.

In order to achieve the above object, there is provided a method for manufacturing a semiconductor device including the first step of forming a nitrogen-containing oxide film on a substrate as a gate insulating film; the second step of annealing the gate insulating film in an atmosphere containing oxygen; the third step of annealing the gate insulating film in an oxygen-free, inert atmosphere; and the fourth step of forming an electrode film in the gate insulating film which has been annealed twice.

In this manufacturing method, the gate insulating film made of the nitrogen-containing oxide film is annealed in an atmosphere containing oxygen so that traps of a hole, such as OH groups, formed in the gate insulating film by the introduction of nitrogen are excluded from the gate insulating film. Moreover, the disorder of the interface structure between the substrate and the gate insulating film is restored, with a reduction of interface level. The gate insulating film is annealed in an oxygen-free, inert atmosphere, whereupon nitrogen that is instable in bonding is excluded to outside of the gate insulating film. In addition, the bonding between nitrogen that is instable in bonding and the oxide constituting the gate insulating film can be stabilized so that the occurrence of NBTI can be suppressed. In this way, instable nitrogen contributing to the hole trapping (i.e. a positive fixed charge) can be removed from the gate insulating film without alteration of the manufacturing process and device structure.

The above and other objects, features and advantages of the present invention will become apparent from the following description and the appended claims, taken in conjunction with the accompanying drawings in which like parts or elements denoted by like reference symbols.

### BRIEF DESCRIPTION OF THE DRAWINGS

FIGS. 1A to 1D are, respectively, a schematic sectional view illustrating the steps of manufacturing a semiconductor device according to the present invention.

FIGS. 1E to 1G are, respectively, a schematic sectional view illustrating the steps of manufacturing the semiconductor device subsequent to FIG. 1D.

### DETAILED DESCRIPTION OF THE PREFERRED EMBODIMENT

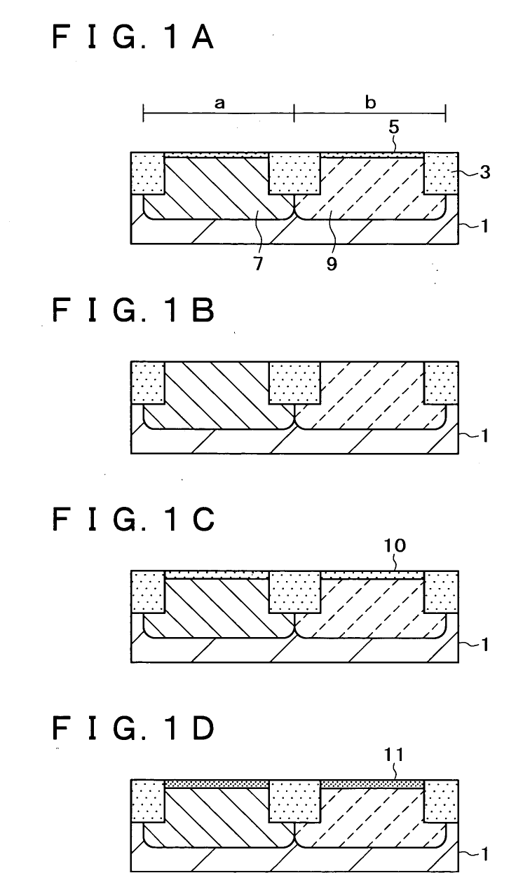

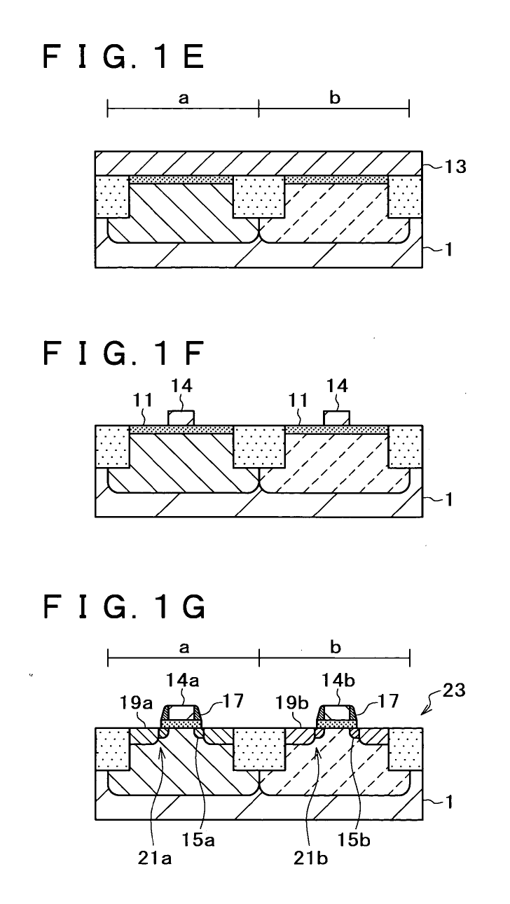

The method for manufacturing a semiconductor device according to the present invention is described in detail with reference to FIGS. 1A to 1G. In these figures, the manufacture of a CMOS semiconductor having a dual gate structure according to an embodiment of the invention is illustrated.

As shown in FIG. 1A, a field oxide film (element isolation region) 3 is formed on a substrate 1 made of single crystal silicon to isolate the surface side of the substrate 1 into an NMOS region “a” and a PMOS region “b”. Next, a sacrificial oxide film 5 is formed on an exposed surface of the substrate 1, and a p-well 7 is formed in the NMOS region “a” and an n-well 9 is formed in the PMOS region “b” by ion implantation through the sacrificial oxide film 5. Impurities for threshold control are, respectively, ion implanted into the NMOS region “a” and the PMOS region “b”.

The above sequence of steps are carried out by application of an ordinary CMOS process, after which, as shown in FIG. 1B, the sacrificial oxide film 5 is separated from the surface of the substrate 1 so that the surface of the substrate 1 is exposed.

Thereafter, as shown in FIGS. 1C and 1D, a gate insulating film 11 made of a nitrogen-containing oxide film (i.e. silicon oxynitride film) is formed on the substrate 1. The gate insulating film 11 can be formed, for example, according to any of the following procedures (1) to (3).

According to the procedure (1), as shown in FIG. 1C, a nitrogen-free oxide film (silicon oxide film) 10 is formed. Thereafter, the film is nitrided by application of a plasma to introduce nitrogen into the oxide film 10, thereby obtaining a gate insulating film made of silicon oxynitride as shown in FIG. 1D.

According to the procedure (2), as shown in FIG. 1C, a nitrogen-free oxide film (silicon oxide film) is formed, followed by annealing in an atmosphere of a nitrogen monoxide (NO) gas or a dinitrogen oxide (N₂O) gas to form a gate insulating film obtained by nitriding the oxide film and made of silicon oxynitride as shown in FIG. 1D. This annealing treatment may be either furnace annealing or RTA (rapid thermal annealing).

The procedure (3) is carried out such that the surface of the substrate 1 is subjected to nitriding and oxidation by furnace oxidation (oxidation) in an atmosphere of a NO gas or N₂O gas to allow silicon oxynitride to be grown, thereby providing a gate insulating film 11.

After the gate insulating film 11 made of silicon oxynitride has been formed on the surface of the substrate 1 according to any one of the above procedures, two annealing treatments including a first annealing treatment and a second annealing treatment, which are prominent features of the present invention, are performed. The first and second. annealing treatments may be carried out in this or reverse order.

The first annealing treatment is carried out in an atmosphere containing oxygen. This annealing treatment is carried out, for example, by RTA or furnace annealing. In this annealing treatment, oxidation proceeds at the interface between the gate insulating film 11 and the substrate 1. In the sense, the first annealing should be conducted while appropriately controlling oxygen pressure and temperature conditions in the annealing atmosphere so as to suppress the gate insulating film from being thickened and nitrogen from being segregated in the gate insulating film.

An instance of such controlling conditions is such that for RTA, the annealing is effected in an atmosphere of oxygen gas reduced to 6.66×10² Pa to 1.33×10⁴ Pa at 900° C. to 1000° C. for about 30 seconds. In this manner, an increment in thickness of the gate insulating film 11 resulting from the oxidation can be suppressed to an extent of 0.5 nm or below.

The first annealing treatment may be carried out in an atmosphere of a mixed gas of nitrogen or an inert gas that is not reactive with Si and oxygen gas. In this case, the treating atmosphere may be at reduced pressure or at an atmospheric pressure. Depending on the partial pressures of oxygen gas and an inert gas and the temperature conditions, the thickening of the gate insulating film and segregation of nitrogen in the gate insulating film, both otherwise caused by the oxidation, can be suppressed.

The second annealing treatment is carried out in an oxygen-free, inert atmosphere. This annealing treatment is effected, for example, by RTA or furnace annealing. The term “oxygen-free, inert atmosphere” used herein is intended to mean such an inert atmosphere that an increment in thickness of the gate insulating film by oxidation does not occur. Accordingly, the treating atmosphere should be a reduced or atmospheric pressure atmosphere of nitrogen gas or an inert gas such as argon, or in vacuum. Moreover, the atmosphere may contain a very small amount of oxygen within a range of not causing an increment in thickness of the gate insulating film 11. For instance, a very small amount oxygen of 10 ppb (ppb by volume) or below, which would be inevitably contained from the standpoint of manufacturing, may be present in a gas to be used.

The second annealing treatment should preferably be carried out within a temperature range wherein nitrogen is not re-distributed greatly through the gate insulating film 11. To this end, the second annealing is carried out at a temperature within a range of 900° C. to 1200° C.

An instance of the second annealing treatment is such that for RTA, the treatment is carried out in a reduced atmosphere of oxygen at 1000° C. for about 20 seconds.

It will be noted that the first and second annealing treatments may be carried out continuously in the same treating chamber or separately in different chambers or devices. In addition, the substrate 1 may be released to air between the first and second annealing treatments, or other steps such as cleaning may be interposed therebetween.

After completion of the two annealing treatments, an electrode film 13 made, for example, of polysilicon is formed over the entire surface of the substrate 1 as is particularly shown in FIG. 1E.

Next, as shown in FIG. 1F, the electrode film 13 is processed in a desired pattern to form a gate electrode 14. In this connection, the electrode film 13 is etched in the pattern using, as a mask, a resist pattern (not shown) formed by a lithographic procedure, and after the etching, the resist pattern is removed.

Subsequently, as shown in FIG. 1G, impurities for forming LDD diffusion layers 15a, 15b at the NMOS region “a” and PMOS region “b” are introduced by ion implantation using, as a mask, the gate electrode 14 and a resist pattern, not shown. For the implantation, phosphorus (P) is, for example, introduced into the NMOS region “a” as an n-type impurity and boron (B) is likewise introduced into the PMOS region “b” as a p-type impurity. Thereafter, a side wall insulating film 17 made, for example, of silicon oxide is formed on side walls of the respective gate electrodes 14. It will be noted that the gate insulating film 11 is removed from the substrate 1 in the step of etching the silicon oxide film back upon formation of the side wall insulating film 17.

Next, impurities for forming source/drain diffusion layers 19a, 19b are introduced into the NMOS region “a” and PMOS region “b” by ion implantation through the mask of the gate electrode 14, the side wall insulating film 17 and a resist pattern, not shown. For the implantation, phosphorus (P) is, for example, introduced into the NMOS region “a” as an n-type impurity and boron (B) is likewise introduced into the PMOS region “b” as a p-type impurity.

According to the two ion implantation procedures stated above, the phosphorus (P) is introduced into the gate electrode 14a of the NMOS region “a” as an n-type impurity and boron (B) is introduced into the gate electrode 14b of the PMOS region “b” as a p-type impurity.

In this way, a semiconductor device 23 is formed as having NMOS 21a and PMOS 21b on the surface side of the substrate 1. This semiconductor device 23 has a dual gate structure wherein the n-type impurity is introduced into the gate electrode 14a of NMOS 21a and the p-type impurity is introduced into the gate electrode 14b of the PMOS 21b.

According to the manufacturing method stated hereinabove, as illustrated in FIG. 1D, the gate electrode 11 made of silicon oxynitride is formed, after which the gate insulating film 11 is annealed (first annealing treatment) in an atmosphere containing oxygen to exclude, from the gate insulating film 11, hole traps such as OH groups formed in the gate insulating film 11 through introduction of nitrogen. In addition, the disorder in crystal state at the interface between the substrate 1 and the gate insulating film 11 is restored, thereby resulting in the reduction of interface level.

Further, the annealing (second annealing treatment) of the gate insulating film 11 in an oxygen-free, inert atmosphere permits nitrogen, which exists in the gate insulating film 11 as being instable in bondage, to be excluded to outside of the gate insulating film 11. At the same time, the bonding between the instably bonded nitrogen and oxide (silicon oxide) can be stabilized in the gate film 11. In this manner, instable nitrogen (positive fixed charge) contributing to hole trapping can be excluded from the gate insulating film.

The hole trapping factors can be removed from the gate insulating film 11 when the two annealing treatments are carried out, and thus, the disorder in crystal state at the interface with the substrate 1 can be restored. This makes it possible to suppress NBTI from occurring.

Especially, according to the manufacturing method of the present invention as illustrated in this embodiment, the improvement of NBTI becomes possible without altering the manufacturing process and element structure but only by addition of the first annealing treatment and the second annealing treatment to the manufacturing process.

Moreover, such improvement ensures high reliability (prolonged life) of the resulting semiconductor device. More particularly, the characteristic variation of MOS transistor ascribed to NBTI can be made small, so that the life before the device does not work owing to the characteristic variation is prolonged, thereby ensuring the manufacture of a semiconductor device that stably works.

In addition, the semiconductor device can be made high in performance. More particularly, with a MOS transistor of a great characteristic variation, it is necessary to design the device so as to allow a larger margin sufficient to appropriately work after the variation. The design permitting such a larger margin leads to degradation of device performance. Thus, the use of a MOS transistor whose characteristic variation is small enables one to design and manufacture a high-performance (e.g. high-speed) device.

In the foregoing embodiment, the present invention has been illustrated to suit it for the application to the manufacturing method of a semiconductor device having CMOS arrangement. However, the present invention is widely applicable to semiconductor devices using a nitrogen-containing.oxide film as a gate insulating film, with similar effects of preventing the occurrence of NBTI being obtained.

While a preferred embodiment of the present invention has been described using specific terms, such description is for illustrative purposes only, and it is to be understood that changes and variations may be made without departing from the spirit or scope of the following claims.

What is claimed is:

1. A method for manufacturing a semiconductor device comprising:
the first step of forming a nitrogen-containing oxide film on a substrate as a gate insulating film;
the second step of annealing said gate insulating film in an atmosphere containing oxygen;
the third step of annealing said gate insulating film in an oxygen-free, inert atmosphere; and
the fourth step of forming an electrode film in said gate insulating film which has been annealed twice.

2. The method according to claim 1, wherein the atmosphere containing oxygen in said second step consists of a atmosphere of a pressure-reduced oxygen gas or an atmosphere of a mixed gas of oxygen gas and an inert gas.

3. The method according to claim 1, wherein said third step is carried out at a temperature ranging from 900° C. to 1200° C.

4. The method according to claim 1, wherein said second and third steps are carried out in this or reversed order.
